(19) United States
(12) Patent Application Publication
(10) Pub. No.: US 2025/0357172 A1
(43) Pub. Date: Nov. 20, 2025

(54) ELECTROSTATIC CHUCK, METHOD OF MANUFACTURING ELECTROSTATIC CHUCK, AND DEVICE FOR MANUFACTURING DISPLAY APPARATUS

(71) Applicant: Samsung Display Co., LTD., Yongin-si (KR)

(72) Inventors: Daeyoung OH, Yongin-si (KR); Jaehan KIM, Yongin-si (KR); Seungho MYOUNG, Yongin-si (KR)

(21) Appl. No.: 19/058,292

(22) Filed: Feb. 20, 2025

(30) Foreign Application Priority Data
May 20, 2024 (KR) 10-2024-0065357

(51) Int. Cl. H01L 21/683; B23K 26/362; B23K 101/36

(52) U.S. Cl. CPC H01L 21/6833; B23K 26/362; B23K 2101/36

(57) ABSTRACT

An electrostatic chuck includes a first insulating layer, a second insulating layer, and an electrode layer disposed between the first insulating layer and the second insulating layer, wherein the first insulating layer includes a first zone and a second zone disposed on a surface that is facing in a first direction and that is disposed far away from the second insulating layer, wherein the second zone at least partially surrounds the first zone, and wherein a first ablation threshold value of the first insulating layer in the first zone is different from a second ablation threshold value of the first insulating layer in the second zone.

This application claims priority to Korean Patent Application No. 10-2024-0065357, filed on May 20, 2024, and all the benefits accruing therefrom under 35 U.S.C. § 119, the content of which in its entirety is herein incorporated by reference.

### BACKGROUND

### 1. Field

The invention relates to an electrostatic chuck and a device that may include the electrostatic chuck, and more particularly, to an electrostatic chuck, a method of manufacturing the electrostatic chuck, and a device for manufacturing a display apparatus that includes the electrostatic chuck.

### 2. Description of the Related Art

In addition to manufacturing various semiconductor chips, such as processors and memories, display apparatuses or display panels including light-emitting diodes may be manufactured in various process facilities or chambers.

In the manufacturing process of semiconductor devices and the manufacturing process of display apparatuses, a chuck for fixing a wafer or substrate to a stage is typically used. For example, the chuck may include a mechanical chuck using a clamp or vacuum and an electric chuck, such as an electrostatic chuck, which uses an electric force to fix the substrate to the stage.

### SUMMARY

Laser etching may be performed to form holes in a part of a display apparatus. In an embodiment, the display apparatus may be fixed to one surface of an electrostatic chuck, for example, and may etch a part of a display panel by irradiating a laser into a certain region of the display apparatus. In this process, a part of the laser may remove a deposition layer that is disposed on a substrate of the display apparatus, pass through the substrate, and may be irradiated onto a surface of the electrostatic chuck that is disposed to be in close contact with the display apparatus. In this case, a part of a surface of the electrostatic chuck may be ablated by the laser, and thus, a part of the particles generated may be adsorbed onto one surface (e.g., a rear surface) of the substrate that is in contact with the electrostatic chuck.

In an embodiment, the adsorbed particles may reduce the transmittance of the substrate. Thus, the electrostatic chuck of which surface is not ablated by the laser, is required during the above-described processes.

According to one or more embodiments, an electrostatic chuck includes a first insulating layer, a second insulating layer, and an electrode layer disposed between the first insulating layer and the second insulating layer, wherein the first insulating layer includes a first zone and a second zone disposed on a surface facing in a first direction and that is disposed far away from the second insulating layer, wherein the second zone at least partially surrounds the first zone, and wherein a first ablation threshold value of the first insulating layer in the first zone may be different from a second ablation threshold value of the first insulating layer in the second zone.

In an embodiment, the first ablation threshold value may be greater than the second ablation threshold value.

In an embodiment, when viewed from the first direction, the first zone may include a plurality of opening shapes that are spaced apart from each other.

In an embodiment, at least one of the first insulating layer and the second insulating layer may include aluminum oxide.

In an embodiment, the first ablation threshold value may be about 1000 mJ/cm² or greater.

According to one or more embodiments, a method of manufacturing an electrostatic chuck includes preparing a first insulating layer, a second insulating layer, and an electrode layer disposed between the first insulating layer and the second insulating layer, and irradiating a laser to a first zone disposed on a first surface of the first insulating layer that is facing a first direction and that is disposed far away from the second insulating layer.

In an embodiment, the irradiating of the laser may include sintering the first insulating layer in the first zone.

In an embodiment, the irradiating of the laser may include increasing an ablation threshold value of the first insulating layer in the first zone.

In an embodiment, when viewed from the first direction, the first zone may include a plurality of opening shapes that are spaced apart from each other.

In an embodiment, the method may further include arranging a mask including an opening overlapping the first zone on the first surface of the first insulating layer.

In an embodiment, in the irradiating of the laser, the laser may be irradiated to the mask.

In an embodiment, in the irradiating of the laser, the laser may be selectively irradiated to the first zone.

In an embodiment, an energy density of the laser may be in a range of about 80 mJ/cm² to about 90 mJ/cm².

In an embodiment, the electrode layer may be disposed on the first insulating layer, the second insulating layer may be disposed on the first insulating layer, and the laser may be irradiated to the first surface of the first insulating layer which is disposed under the first insulating layer.

According to one or more embodiments, a device for manufacturing a display apparatus includes a chamber, an electrostatic chuck disposed in the chamber and being in close contact with a display substrate, and an etching unit configured to irradiate a laser to the display substrate, wherein the electrostatic chuck may include a first insulating layer and a second insulating layer that are in contact with the display substrate, and an electrode layer disposed between the first insulating layer and the second insulating layer, wherein the first insulating layer may include a first zone and a second zone that are in contact with the display substrate, the second zone at least partially surrounding the first zone, and wherein a first ablation threshold value of the first insulating layer in the first zone may be different from a second ablation threshold value of the first insulating layer in the second zone.

In an embodiment, the first ablation threshold value may be greater than the second ablation threshold value.

In an embodiment, the first zone may include a plurality of opening shapes that are spaced apart from each other.

In an embodiment, at least one of the first insulating layer and the second insulating layer may include aluminum oxide.

In an embodiment, the first ablation threshold value may be about 1000 mJ/cm² or greater.

In an embodiment, the etching unit may be disposed outside the chamber.

In an embodiment, the display substrate may be disposed under the electrostatic chuck, and the etching unit may be disposed under the display substrate, and a direction of the laser may be directed entirely upward.

In an embodiment, the etching unit may be configured to irradiate a laser to the display substrate in a region overlapping the first zone of the first insulating layer.

In an embodiment, the laser may be configured to etch a partial layer of the display substrate, may pass through the other layer of the display substrate and may reach the electrostatic chuck.

### BRIEF DESCRIPTION OF THE DRAWINGS

The above and other aspects, features, and advantages of certain embodiments of the invention will be more apparent from the following description taken in conjunction with the accompanying drawings, in which:

FIG. 1 is a cross-sectional view of a device for manufacturing a display apparatus, according to an embodiment;

FIG. 2 is a bottom view of an electrostatic chuck, according to an embodiment;

FIG. 3 is a cross-sectional view of an electrostatic chuck, according to an embodiment;

FIG. 4A is a cross-sectional view illustrating an operation of a method of manufacturing an electrostatic chuck, according to an embodiment;

FIG. 4B is a cross-sectional view illustrating an operation of a method of manufacturing an electrostatic chuck, according to an embodiment;

FIG. 4C is a cross-sectional view illustrating an operation of a method of manufacturing an electrostatic chuck, according to an embodiment;

FIG. 5A is a cross-sectional view illustrating an operation of a method of manufacturing an electrostatic chuck, according to an embodiment;

FIG. 5B is a cross-sectional view illustrating an operation of a method of manufacturing an electrostatic chuck, according to an embodiment;

FIG. 5C is a cross-sectional view illustrating an operation of a method of manufacturing an electrostatic chuck, according to an embodiment;

FIG. 5D is a cross-sectional view illustrating an operation of a method of manufacturing an electrostatic chuck, according to an embodiment;

FIG. 5E is a cross-sectional view illustrating an operation of a method of manufacturing an electrostatic chuck, according to an embodiment;

FIG. 6A is a cross-sectional view illustrating an operation of a method of manufacturing a display apparatus, according to an embodiment;

FIG. 6B is a cross-sectional view illustrating an operation of a method of manufacturing a display apparatus, according to an embodiment;

FIG. 6C is a cross-sectional view illustrating an operation of a method of manufacturing a display apparatus, according to an embodiment;

FIG. 6D is a cross-sectional view illustrating an operation of a method of manufacturing a display apparatus, according to an embodiment;

FIG. 6E is a cross-sectional view illustrating an operation of a method of manufacturing a display apparatus, according to an embodiment;

FIG. 6F is a cross-sectional view illustrating an operation of a method of manufacturing a display apparatus, according to an embodiment;

FIG. 6G is a cross-sectional view illustrating an operation of a method of manufacturing a display apparatus, according to an embodiment;

FIG. 6H is a cross-sectional view illustrating an operation of a method of manufacturing a display apparatus, according to an embodiment;

FIG. 6I is a cross-sectional view illustrating an operation of a method of manufacturing a display apparatus, according to an embodiment;

FIG. 6J is a cross-sectional view illustrating an operation of a method of manufacturing a display apparatus, according to an embodiment;

FIG. 6K is a cross-sectional view illustrating an operation of a method of manufacturing a display apparatus, according to an embodiment;

FIG. 6L is a cross-sectional view illustrating an operation of a method of manufacturing a display apparatus, according to an embodiment;

FIG. 7 is a plan view of a display apparatus manufactured by using the device for manufacturing a display apparatus, according to an embodiment;

FIG. 8 is a cross-sectional view of the display apparatus of FIG. 7 taken along a line VIII-VIII′ of FIG. 7, according to an embodiment; and

FIG. 9 is a cross-sectional view of the display apparatus of FIG. 7 taken along a line IX-IX′ of FIG. 7, according to an embodiment.

### DETAILED DESCRIPTION

Reference will now be made in detail to embodiments, examples of which are illustrated in the accompanying drawings, wherein like reference numerals refer to like elements throughout. In this regard, the present invention may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Since various modifications and various embodiments are possible, specific embodiments are illustrated in the drawings and described in detail in the detailed description. Effects and features of the invention, and a method of achieving them will be apparent with reference to embodiments described in conjunction with the drawings. However, the invention is not limited to the embodiments disclosed herein, but may be implemented in a variety of forms. Hereinafter, the same or corresponding components are denoted by the same reference numerals, and the same reference numerals are assigned, and redundant explanations will be omitted. In the following embodiments, the terms “first”, “second”, etc. were used for the purpose of distinguishing one element from other elements, not a limited sense. In the following embodiments, the singular expression includes a plurality of expressions unless the context is clearly different. In the following embodiments, the terms such as comprising or having are meant to be the features described in the specification, or the elements are present, and the possibility of one or more other features or elements will be added, is not excluded in advance. In the following embodiments, when a portion such as a layer, a region, an element or the like is on other portions, this is not only when the portion is on other elements, but also when other elements are interposed therebetween. In the drawings, for convenience of explanation, the sizes of elements may be exaggerated or reduced. For example, since the size and thickness of each component shown in the drawings are arbitrarily indicated for convenience of explanation, the invention is not necessarily limited to the illustration. In the case where some embodiments may be implemented in the present specification, a specific process order may be performed differently from the order described. For example, two processes described in succession may be substantially performed at the same time, or in an opposite order to an order to be described. In the specification, “A and/or B” is A, B, or A and B. In addition, “at least one of A and B” is A, B, or A and B. The x-axis, the y-axis, and the z-axis are not limited to three axes on a Cartesian coordinate system and may be interpreted in a broad sense including the same. For example, the x-axis, the y-axis, and the z-axis may be perpendicular to each other, but may refer to different directions that are not orthogonal to each other.

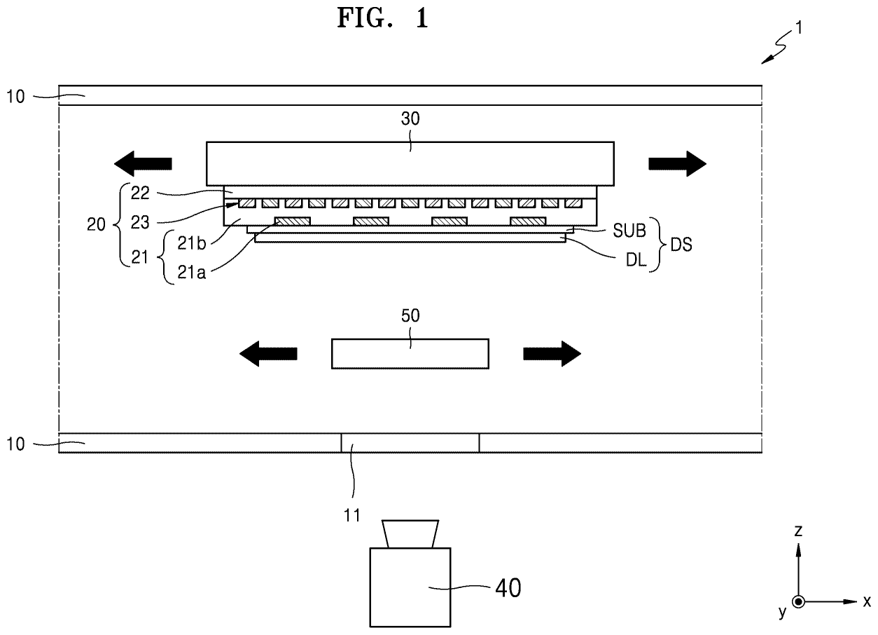

FIG. 1 is a cross-sectional view of a device 1 for manufacturing a display apparatus, according to an embodiment.

In an embodiment and referring to FIG. 1, the device 1 for manufacturing a display apparatus may include a chamber 10, an electrostatic chuck 20, a first moving unit 30, an etching unit 40, and a second moving unit 50. In an embodiment, the device 1 for manufacturing a display apparatus may be etching equipment.

The chamber 10 may provide a space in which a process performed by the device 1 for manufacturing a display apparatus may be performed. In other words, a process performed by the device 1 for manufacturing a display apparatus, i.e., a process of manufacturing the display apparatus, may be performed inside the chamber 10, where the pressure inside the chamber 10 may be controlled by a pressure control unit (not shown) including a pump. The chamber 10 may extend in one direction (e.g., along an x-axis). Other components of the device 1 for manufacturing a display apparatus, for example, the first moving unit 30 and the second moving unit 50 may move in one direction (e.g., along the x-axis) inside the chamber 10.

The first moving unit 30 may be arranged in the chamber 10 and may be configured to move in one direction (e.g., along the x-axis) inside the chamber 10. For example, the first moving unit 30 may be connected to a gantry installed in the chamber 10. The first moving unit 30 may move other components connected to the first moving unit 30 within the chamber 10. For example, the electrostatic chuck 20 and a display substrate DS may be coupled to the first moving unit 30 and may move within the chamber 10.

The electrostatic chuck 20 may be coupled to the first moving unit 30. In an embodiment, the electrostatic chuck 20 may be screwed to the first moving unit 30 and fixed thereto. In an embodiment, the electrostatic chuck 20 may be coupled to a lower surface of the first moving unit 30, i.e., a surface facing a −z direction. The electrostatic chuck 20 coupled to the first moving unit 30 may move integrally with the first moving unit 30.

The electrostatic chuck 20 may include a first insulating layer 21, a second insulating layer 22, and an electrode layer 23 disposed between the first insulating layer 21 and the second insulating layer 22. In an embodiment, the second insulating layer 22 may be disposed on the first insulating layer 21, i.e., in a +z direction of the first insulating layer 21. The first insulating layer 21 may include a first portion 21a and a second portion 21b. A detailed configuration of the electrostatic chuck 20 will be described below.

The display substrate DS may be disposed under the electrostatic chuck 20, i.e., in a −z direction. The display substrate DS may be an object to be processed by the device 1 for manufacturing a display apparatus, according to an embodiment. The display substrate DS may be in direct contact with a lower surface of the electrostatic chuck 20, i.e., in the −z direction. The display substrate DS may be fixed to the electrostatic chuck 20. For example, the display substrate DS may be fixed to the electrostatic chuck 20 by an electrostatic force applied to the display substrate DS using the electrostatic chuck 20.

The display substrate DS may include a substrate SUB that is in direct contact with the electrostatic chuck 20, and a deposition layer DL disposed on one surface (e.g., a surface facing the −z direction) of the substrate SUB. In an embodiment and referring to FIG. 1, the deposition layer DL is disposed under the substrate SUB, i.e., in the −z direction. However, substantially, when users use the display apparatus, the deposition layer DL may be located on the substrate SUB, i.e., in the +z direction. In other words, the display substrate DS in an upside down state may be processed in the chamber 10. In another embodiment, an upper surface of the display substrate DS and an upper surface of the substrate SUB in the chamber 10 may be directed in the −z direction.

The etching unit 40 may etch the deposition layer DL of the display substrate DS. In an embodiment, the etching unit 40 may be optical equipment, e.g., a laser etching apparatus. In an embodiment, the etching unit 40 may irradiate a laser toward the display substrate DS, for example, in the +z direction. In an embodiment, the etching unit 40 may be located outside the chamber 10. In this case, the chamber 10 may include a window 11 that overlaps the etching unit 40, where the window 11 may allow light to pass therethrough. Thus, the laser irradiated by the etching unit 40 may reach the display substrate DS disposed within the chamber 10.

The second moving unit 50 may be disposed under the display substrate DS, for example, in the −z direction. The second moving unit 50 may be located in the chamber 10 and may be located between the first moving unit 30 and the etching unit 40, for example, between the display substrate DS and the etching unit 40. The second moving unit 50 may collect particles generated when the display substrate DS is etched. In an embodiment, the second moving unit 50 may be a movable tray. In an embodiment, the second moving unit 50 may be configured in such a way that the laser of the etching unit 40 may pass through the second moving unit 50. The second moving unit 50 may move while being dependent on the first moving unit 30 and may move independently with the first moving unit 30.

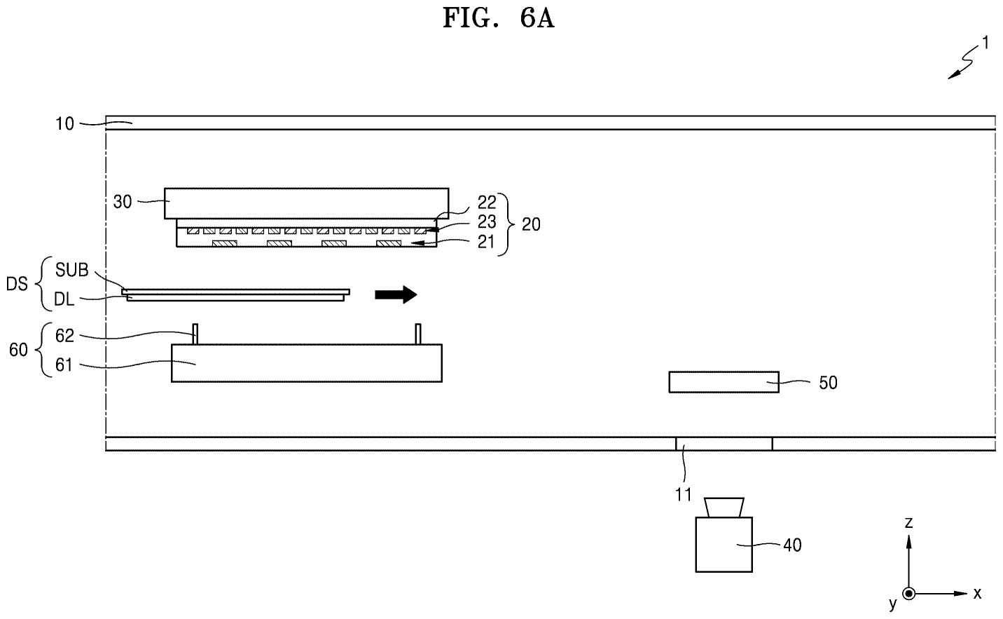

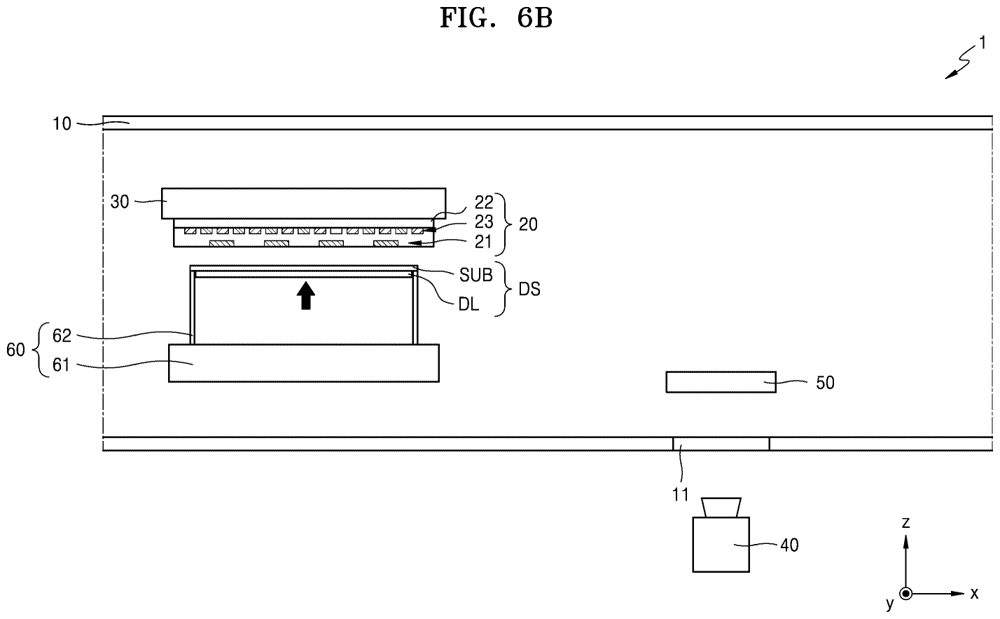

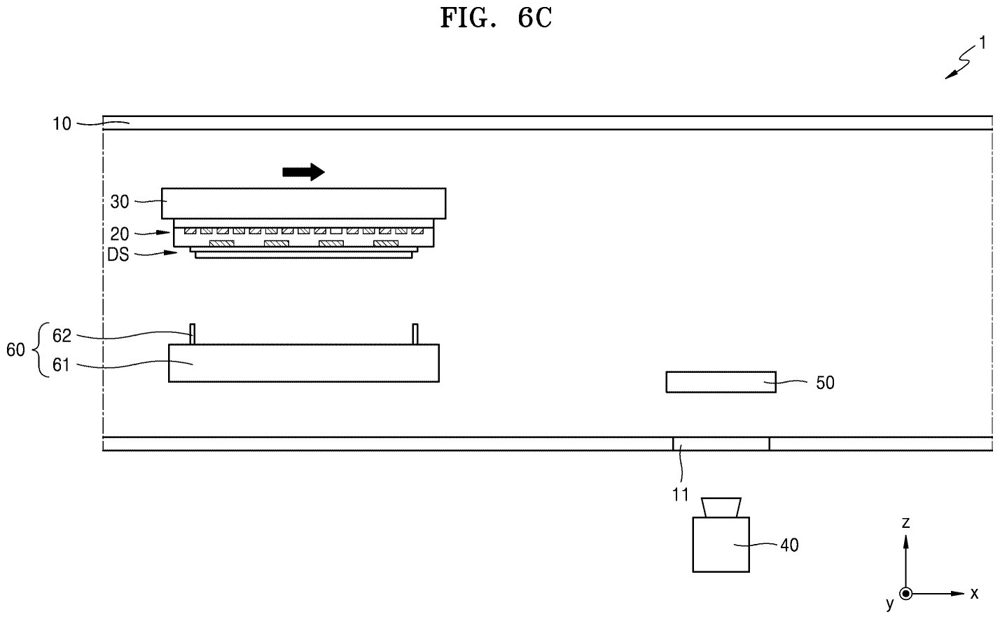

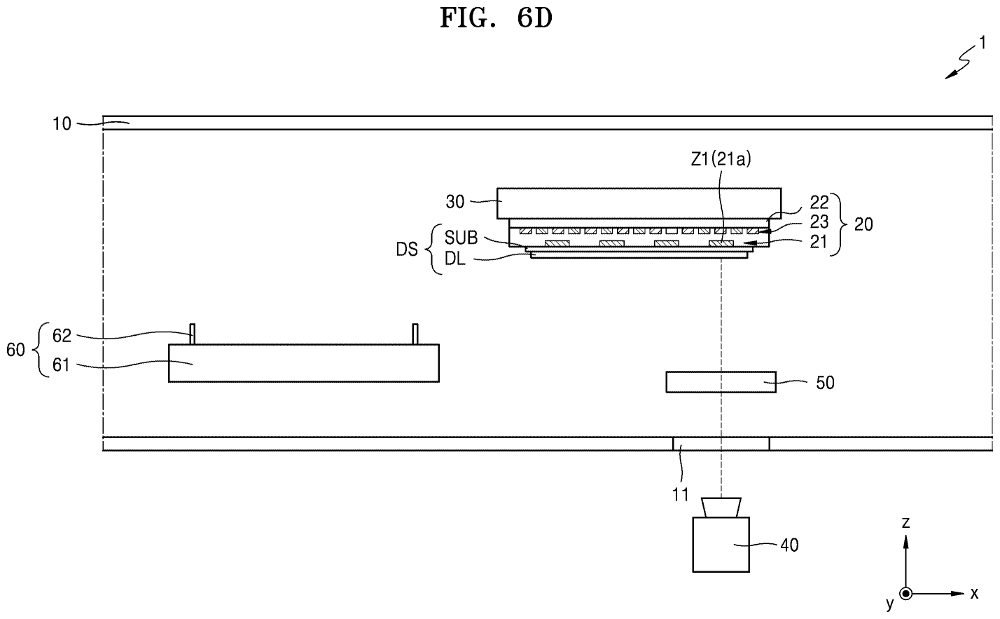

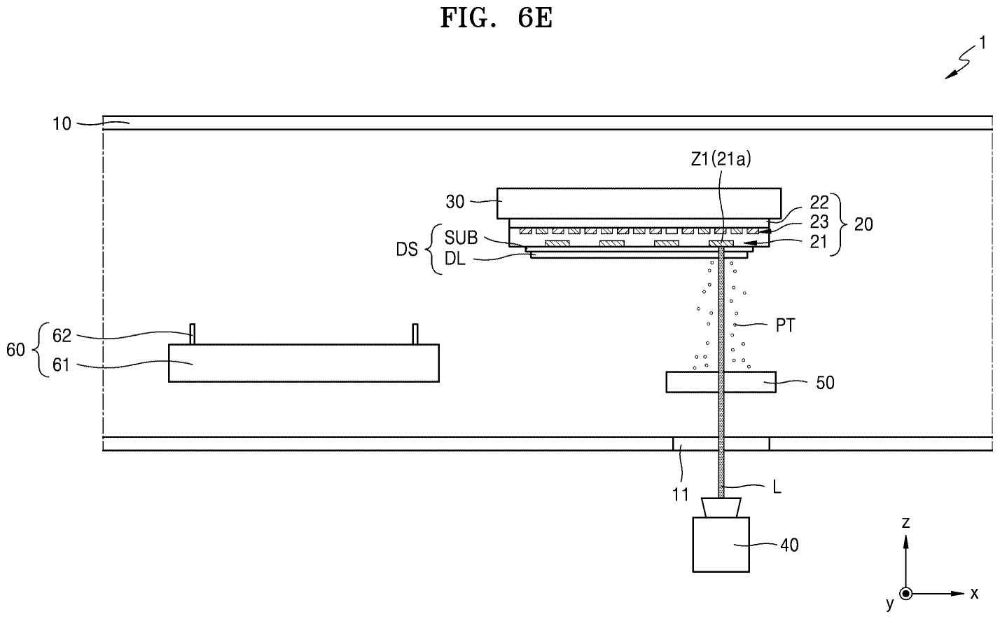

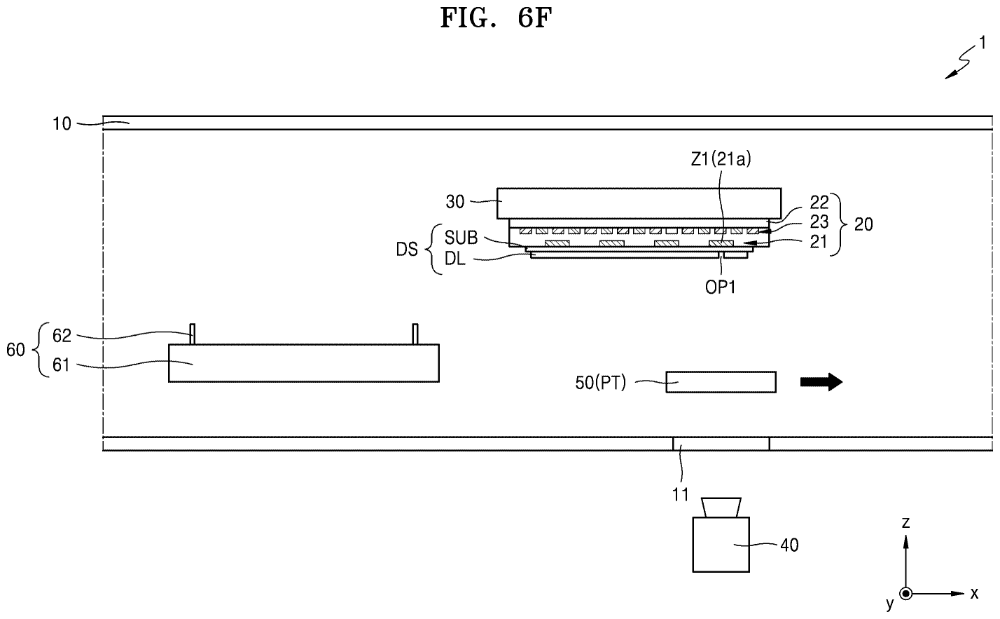

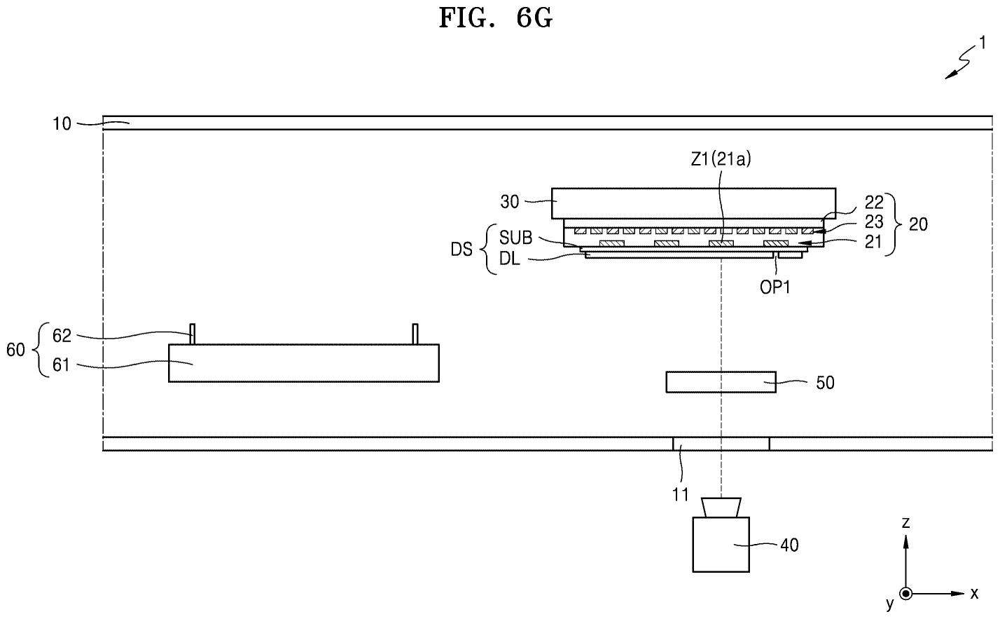

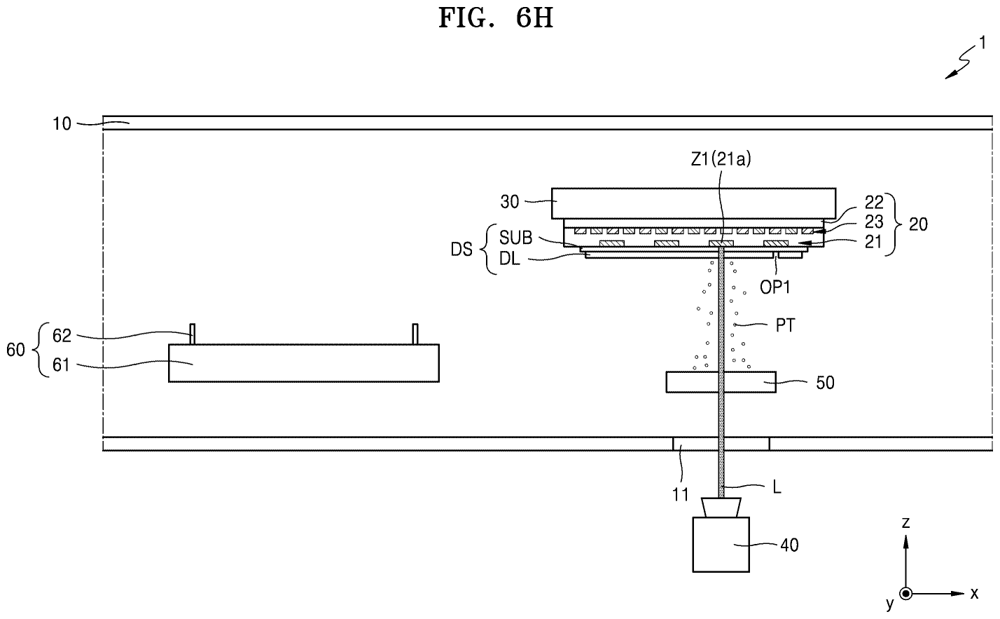

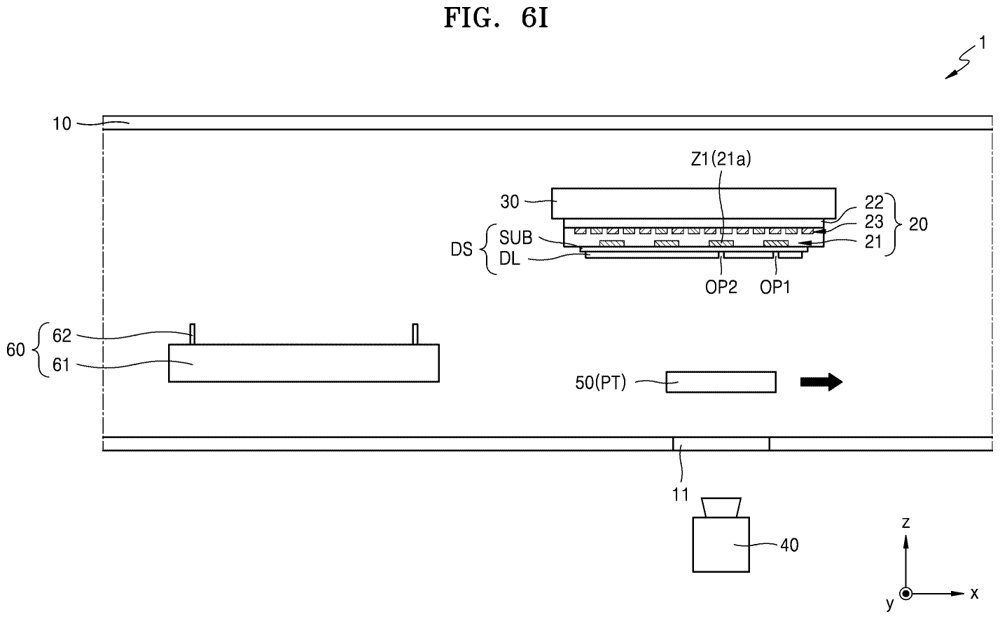

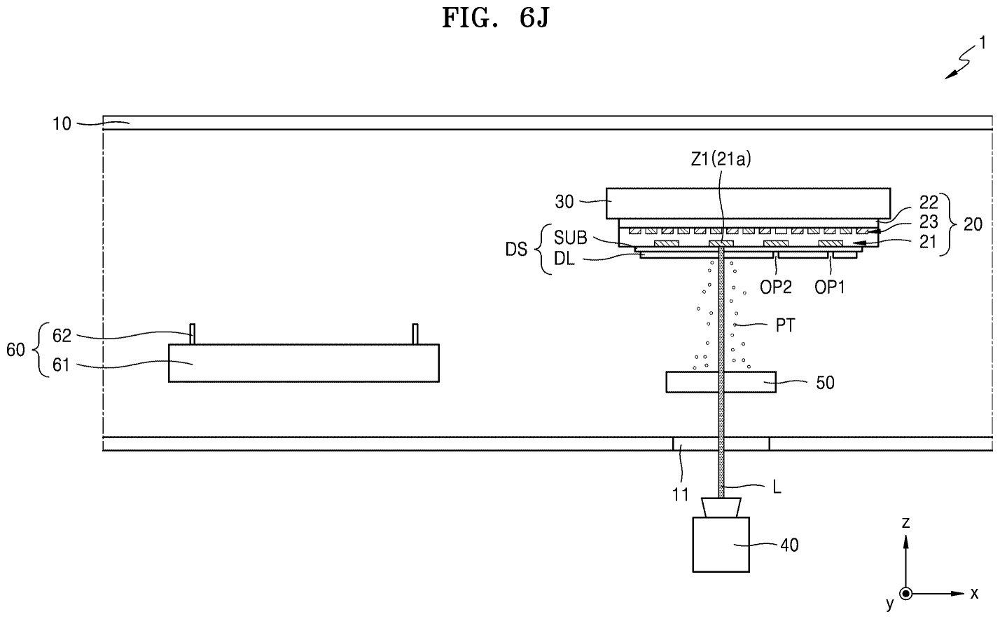

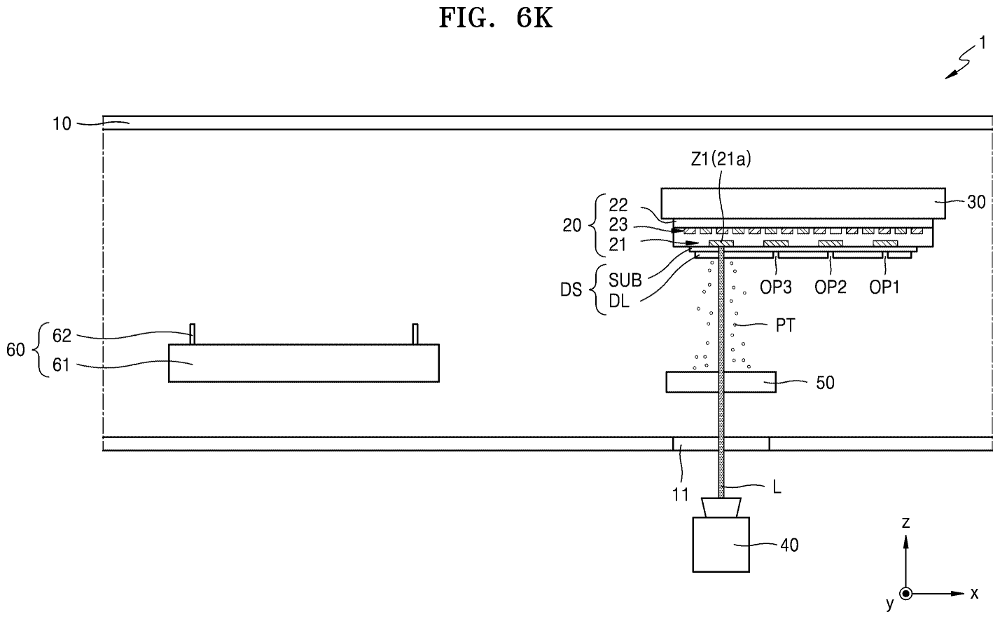

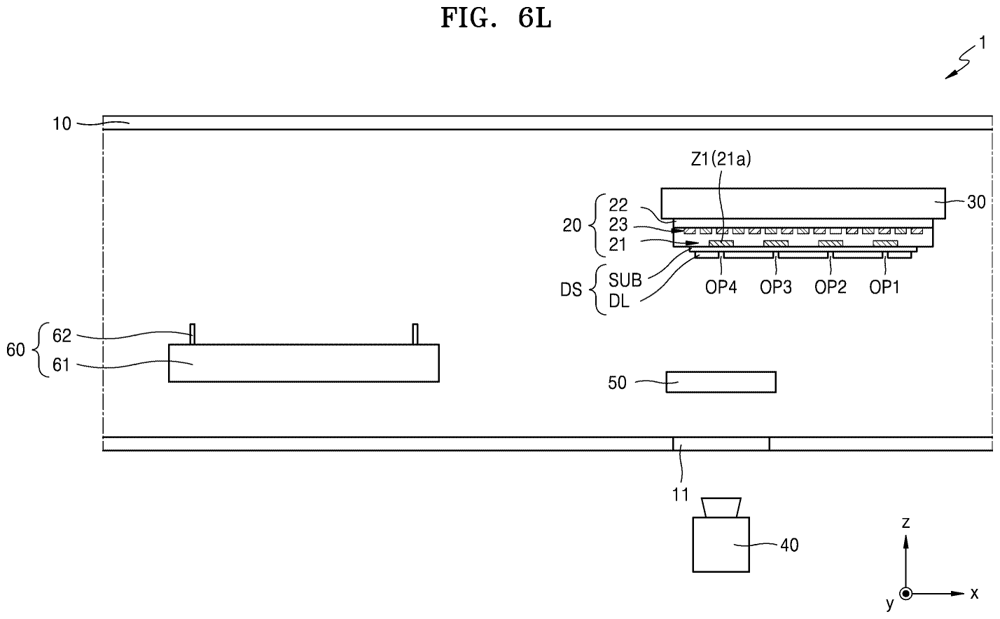

A procedure of processing the display substrate DS that is an object to be processed using the device 1 for manufacturing a display apparatus described with reference to FIG. 1 will be described with reference to FIGS. 6A through 6L.

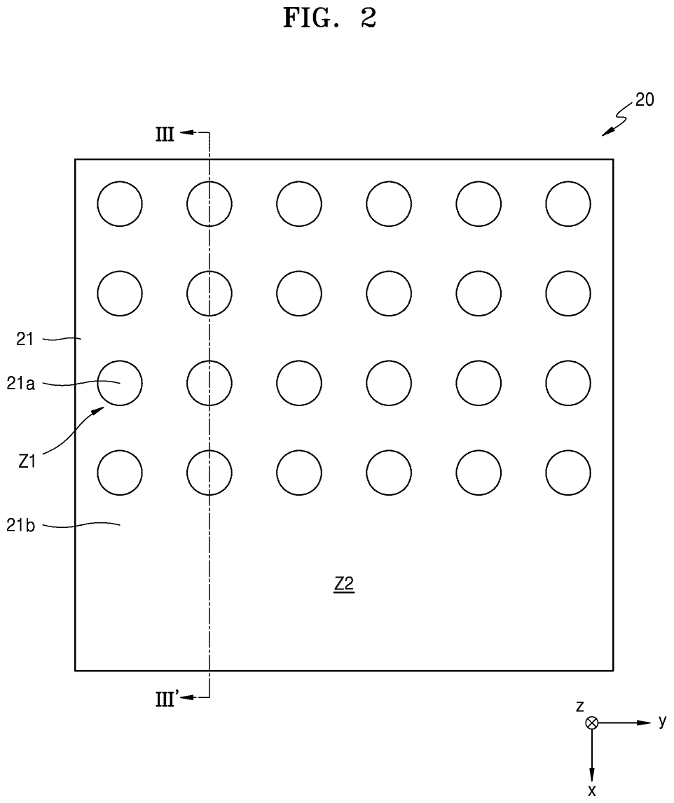

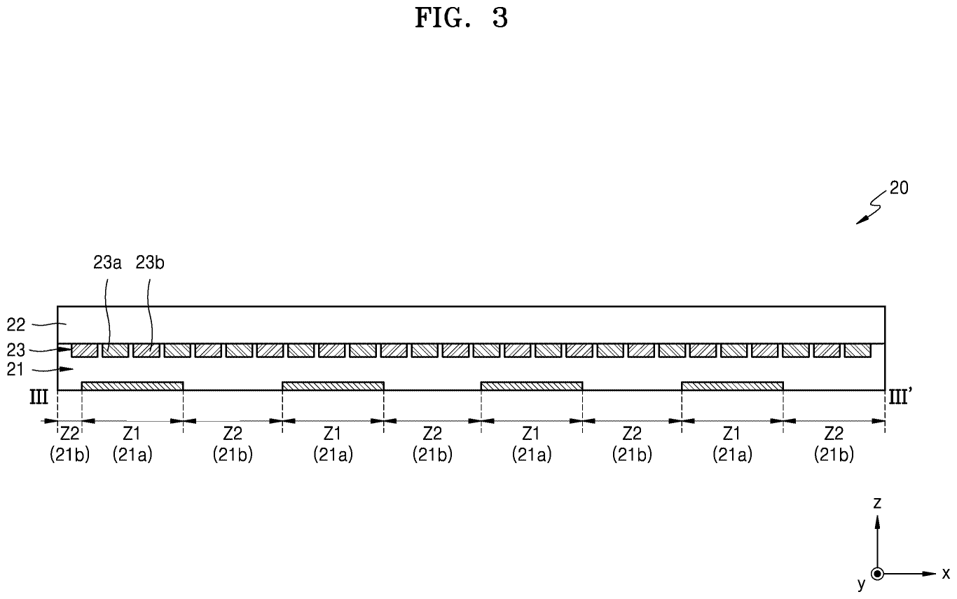

FIG. 2 is a bottom view of an electrostatic chuck, according to an embodiment. FIG. 3 is a cross-sectional view of the electrostatic chuck of FIG. 2 taken along a line III-III′ of FIG. 2, according to an embodiment.

In an embodiment and referring to FIGS. 2 and 3 together, an electrostatic chuck 20 may include a first insulating layer 21, a second insulating layer 22, and an electrode layer 23, where the second insulating layer 22 may be disposed on the first insulating layer 21, and the electrode layer 23 may be disposed between the first insulating layer 21 and the second insulating layer 22.

The first insulating layer 21 may include an insulating material. In an embodiment, the first insulating layer 21 may include aluminum oxide.

In an embodiment, the electrode layer 23 may be disposed within openings formed in the first insulating layer 21, and an upper surface of the electrode layer 23 (e.g., a surface facing the +z direction) may be disposed on the same plane as an upper surface of the first insulating layer 21. In this case, the upper surface of the electrode layer 23 may be in contact with the second insulating layer 22. Of course, embodiments are not limited thereto, and the electrode layer 23 may be disposed between the first insulating layer 21 and the second insulating layer 22 in another configuration.

In an embodiment, the electrode layer 23 may include a plurality of first electrodes 23a and a plurality of second electrodes 23b. The first electrodes 23a and the second electrodes 23b may be alternately disposed in one direction (e.g., along an x-axis or a y-axis). That is, one second electrode 23b may be disposed between two adjacent first electrodes 23a, and one first electrode 23a may be disposed between two adjacent second electrodes 23b.

In an embodiment, a positive direct current voltage may be applied to the first electrodes 23a, and a first electrostatic force may be generated between the first electrodes 23a and the substrate SUB. A negative direct current voltage may be applied to the second electrodes 23b, and a second electrostatic force may be generated between the second electrodes 23b and the substrate.

The electrostatic chuck 20, according to an embodiment, may be a bipolar electrostatic chuck. However, the invention is not limited thereto, and the type of the electrostatic chuck 20 is not limited thereto. For example, in an embodiment, the electrostatic chuck 20 may be a monopolar electrostatic chuck. In this case, a direct current voltage having the same polarity may be applied to the first electrodes 23a and the second electrodes 23b of the electrostatic chuck 20.

The second insulating layer 22 may be disposed on the first insulating layer 21 and the electrode layer 23, and may include an insulating material. In an embodiment, the second insulating layer 22 may include aluminum oxide (Al₂O₃).

In an embodiment, the first insulating layer 21 may include a first portion 21a and a second portion 21b. The first portion 21a of the first insulating layer 21 may overlap a first zone Z1 and the second portion 21b of the first insulating layer 21 may overlap a second zone Z2. In other words, a region in which the first portion 21a is disposed may be understood as the first zone Z1, and a region in which the second portion 21b is disposed may be understood as the second zone Z2.

In an embodiment, the first zone Z1 of the first insulating layer 21 may have a plurality of island-type hole shapes which may be spaced apart from each other in one direction (e.g., along an x-axis or a y-axis). The second zone Z2 may surround the first zone Z1, at least partially (e.g., completely). In FIG. 2, the hole shapes of the first zone Z1 are circular shapes. However, the hole shapes may be variously modified into polygonal shapes, elliptical shapes, and the like.

In an embodiment, the first portion 21a of the first insulating layer 21 may be disposed on a lower surface of the first insulating layer 21, for example, a surface facing the −z direction. In this case, the lower surface of the first insulating layer 21 may be a surface that is in direct contact with the substrate (i.e., SUB of FIG. 1). Thus, the first portion 21a of the first insulating layer 21 may be in direct contact with the substrate (SUB of FIG. 1).

In an embodiment, the first portion 21a of the first insulating layer 21 may be a processed portion. In other words, the first portion 21a may be surface-treated on a part of the first insulating layer 21, rather than forming an opening in the first insulating layer 21 to arrange a separate material. In this case, the second portion 21b may be a portion that is not surface-treated. In an embodiment, the surface treatment may include laser processing.

In an embodiment, the first portion 21a and the second portion 21b of the first insulating layer 21 may have different ablation threshold values. In other words, when the first insulating layer 21 is to be ablated using a laser, the energy density of the laser required to ablate the first portion 21a may be different from the energy density of the laser required to ablate the second portion 21b. In an embodiment, a first ablation threshold value of the first insulating layer 21 may be greater than a second ablation threshold value of the second insulating layer 22. In an embodiment, the first ablation threshold value may be about 1000 mJ/cm² or greater. In an embodiment, the second ablation threshold value may be about 100 mJ/cm² or less. Thus, when a laser having a constant energy density (e.g., about 200 mJ/cm²) is irradiated to the first insulating layer 21, a part (e.g., the first portion 21a) of the first insulating layer 21 may not be ablated, and the other part (e.g., the second portion 21b) of the first insulating layer 21 may be ablated.

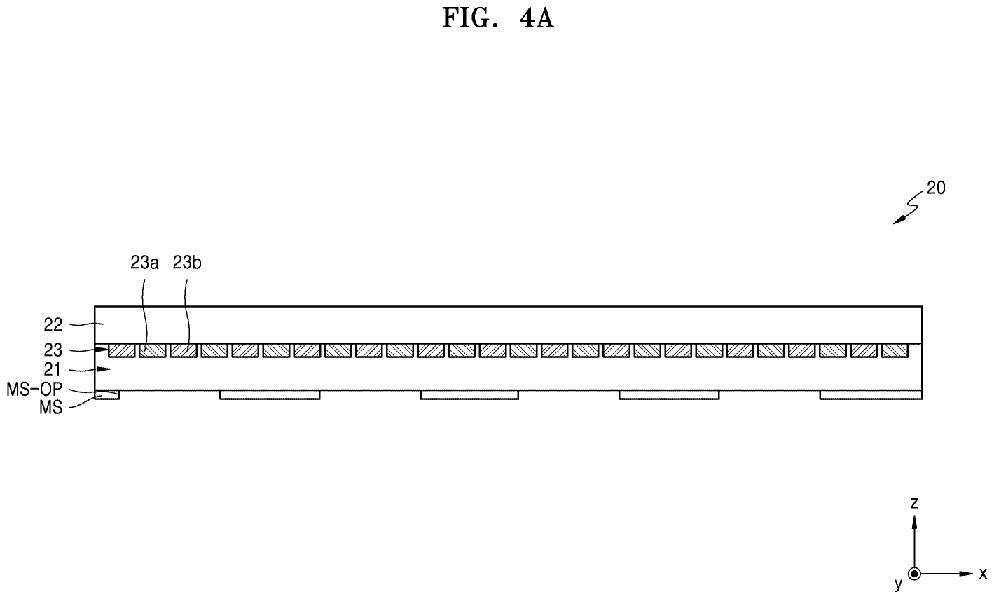

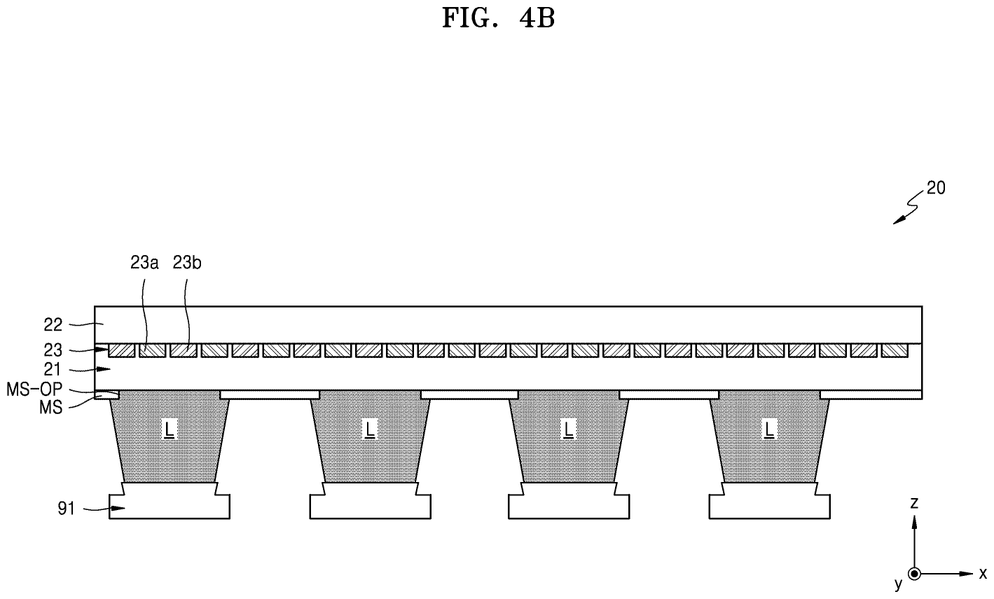

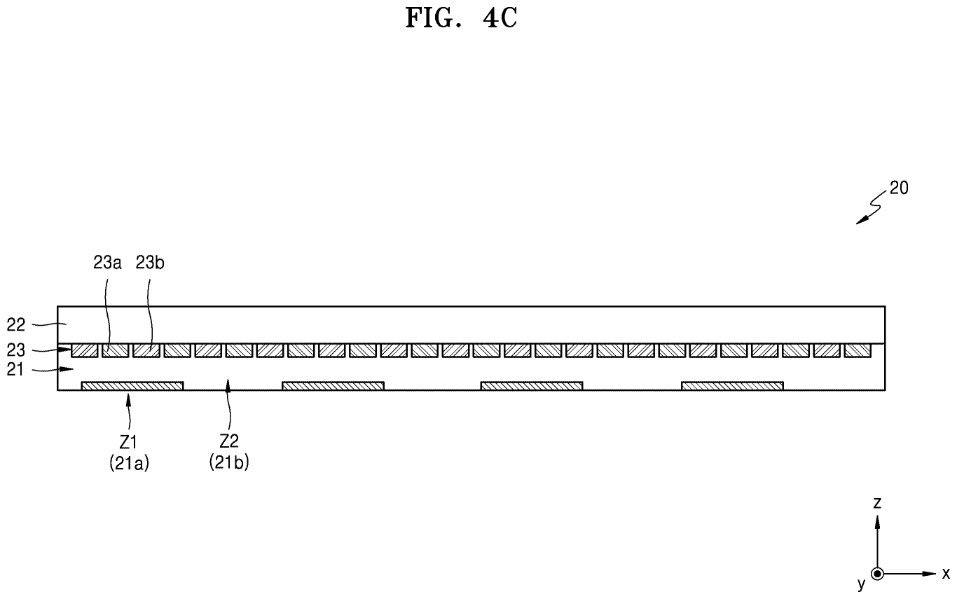

FIGS. 4A, 4B, and 4C are cross-sectional views illustrating operations of a method of manufacturing an electrostatic chuck, according to an embodiment. FIGS. 4A through 4C illustrate operations of a method of manufacturing an electrostatic chuck shown in FIG. 3, according to a first embodiment.

In an embodiment and referring to FIG. 4A, an electrostatic chuck 20 may include a first insulating layer 21, a second insulating layer 22, and an electrode layer 23. In this case, the first insulating layer 21 may be in a state before the first portion (21a of FIG. 3) described above with reference to FIG. 3 is formed. Thus, in a current operation of a process, the first insulating layer 21 may be in the same state as the second portion (21b of FIG. 3) entirely.

In an embodiment, a treatment mask MS may be disposed on the lower surface of the first insulating layer 21, i.e., a surface facing the −z direction. The treatment mask MS may be fixed to the lower surface of the first insulating layer 21 using any suitable means. The treatment mask MS may include a plurality of openings MS-OP, where the openings MS-OP of the treatment mask MS may overlap the first zone (Z1 of FIG. 3). In other words, the openings MS-OP of the treatment mask MS may define a first zone (Z1 of FIG. 3) that is a region in which the first insulating layer 21 is to be surface-treated. The treatment mask MS may cover the first insulating layer 21 in the second zone (Z2 of FIG. 3). On the other hand, a bottom surface image of the treatment mask MS may be similar to a bottom surface image of the first insulating layer 21 shown in FIG. 2.

In an embodiment and referring to FIGS. 4A and 4B together, a laser L may be irradiated to the first insulating layer 21 using a first surface treatment device 91. In an embodiment, the first surface treatment device 91 may be disposed under the electrostatic chuck 20, i.e., in the −z direction and may irradiate the laser L in the +z direction. In an embodiment, a plurality of first surface treatment devices 91 may be provided to respectively correspond to the openings MS-OP of the treatment mask MS. In an embodiment, the plurality of first surface treatment devices 91 may irradiate the laser L simultaneously.

In an embodiment and as shown in FIG. 4B, the width of the laser L may not coincide with the width of the opening MS-OP of the treatment mask MS. Thus, a part of the laser L may pass through the opening MS-OP of the treatment mask MS and may be irradiated to the surface of the first insulating layer 21, and the other part of the laser L may be blocked by the treatment mask MS and may not reach the surface of the first insulating layer 21. Thus, the treatment mask MS may define a region (e.g., the first zone z1 of FIG. 4C) of the first insulating layer 21, which is to be processed through the laser L of the first surface treatment device 91.

In an embodiment, the first surface treatment device 91 may inject a laser L having a certain energy density. For example, the first surface treatment device 91 may inject the laser L having an energy density in a range of about 80 mJ/cm² to about 90 mJ/cm².

In an embodiment, the laser L irradiated to the first insulating layer 21 may not be continuously irradiated but may be irradiated with a certain frequency. For example, the first surface treatment device 91 may repeat a procedure of irradiating the laser L to the first insulating layer 21 for a certain amount of time, not irradiating the laser L for a certain amount of time and then irradiating the laser L for a certain amount of time again. In an embodiment, the procedure may be repeatedly performed multiple times, for example about 800 times.

Of course, the invention is not limited to the energy density of the laser and the number of laser irradiations, and the energy density and the number of irradiations may be changed in various ways depending on the purpose of surface treatment.

In an embodiment, FIG. 4B illustrates that a plurality of first surface treatment devices 91 are separated and spaced apart from each other. However, in another embodiment, a single first surface treatment device 91 may inject a plurality of lasers L which are spaced apart from each other toward the first insulating layer 21. For example, one first surface treatment device 91 may include a plurality of laser injection ports, and each of the plurality of laser injection ports may correspond to each of the openings MS-OP of the treatment mask MS.

In an embodiment and referring to FIGS. 4B and 4C together, the state of the electrostatic chuck 20 of which a surface treatment is completed by the laser L, is shown in FIG. 4C. A portion of the first insulating layer 21 that is surface-treated by the laser L of the first surface treatment device 91 may be defined as a first portion 21a, and a corresponding region may be defined as a first zone Z1. The other portion of the first insulating layer 21, i.e., a portion that is not surface-treated, may be defined as a second portion 21b, and a corresponding region may be defined as a second zone Z2. The surface treatment may include sintering. In other words, the first portion 21a of the first insulating layer 21 may be sintered by the laser L irradiated by the first surface treatment device 91. An ablation threshold value of the first portion 21a of the first insulating layer 21 may be increased. Thus, the first ablation threshold value of the first portion 21a may be different from the second ablation threshold value of the second portion 21b, but these features are the same as the description with reference to FIGS. 2 and 3.

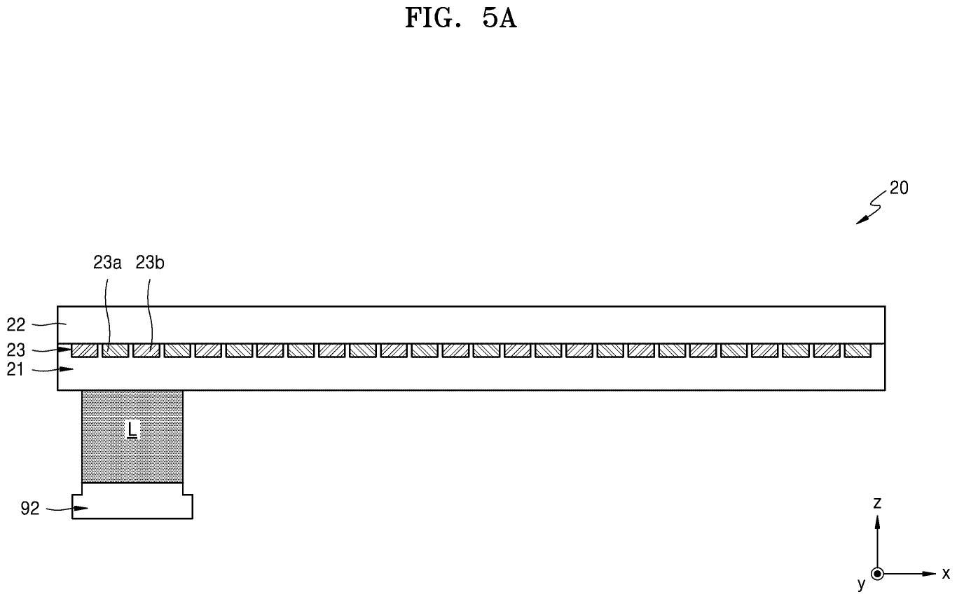

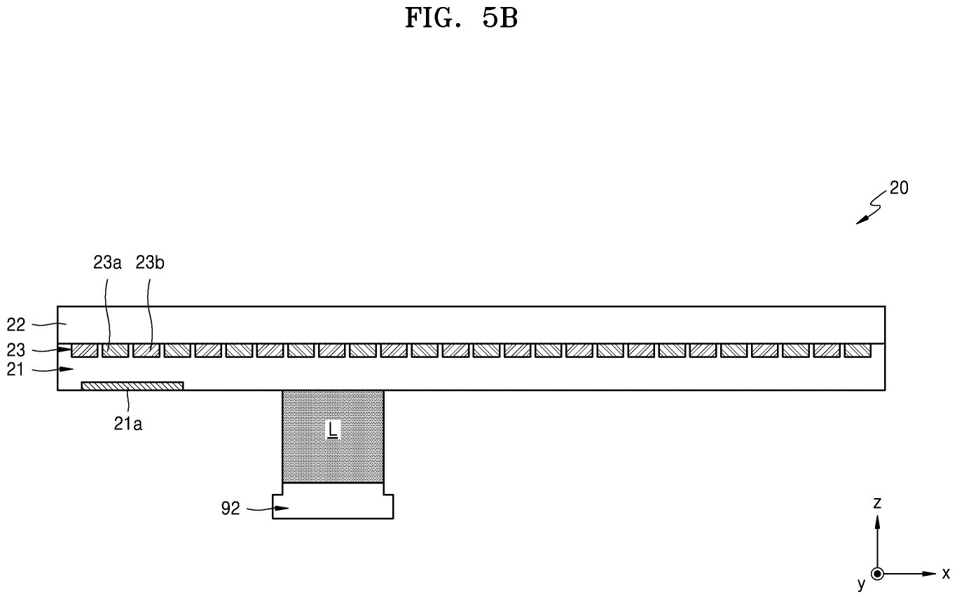

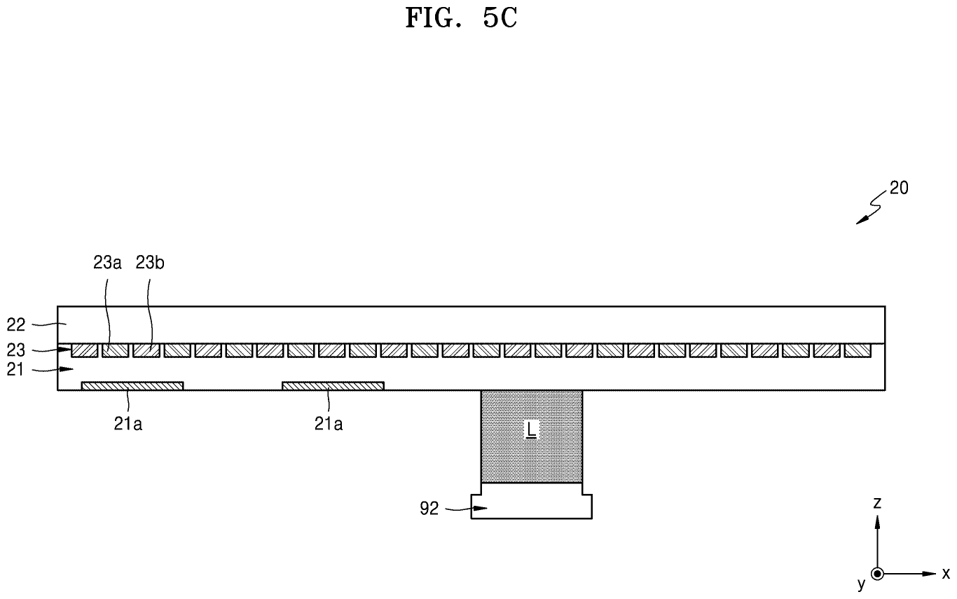

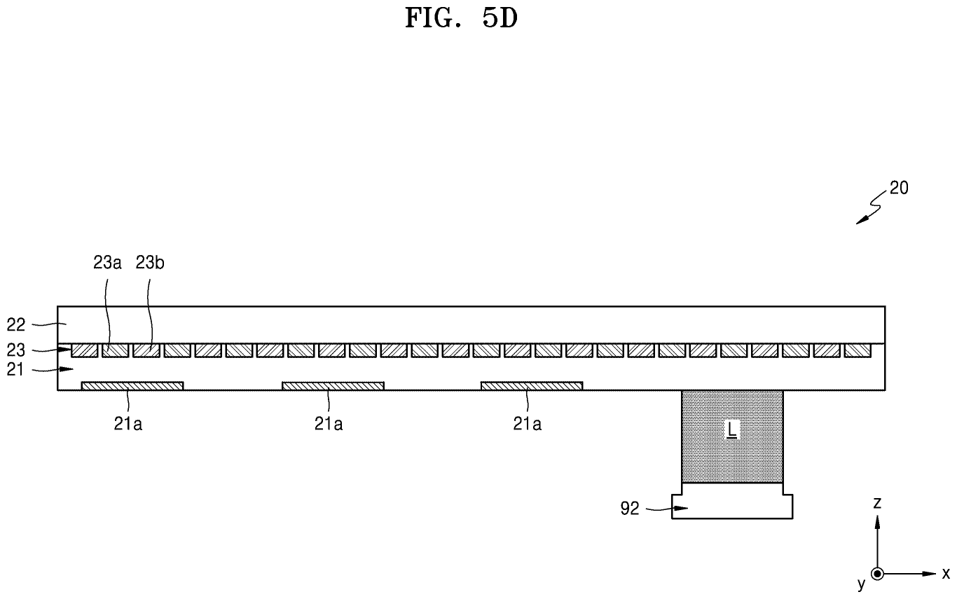

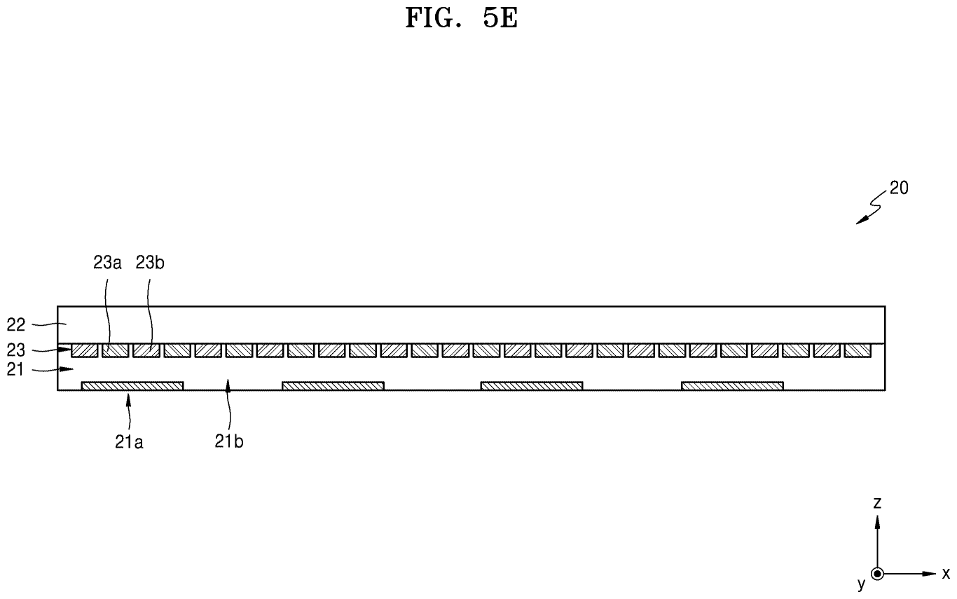

FIGS. 5A, 5B, 5C, 5D, and 5E are cross-sectional views illustrating operations of a method of manufacturing an electrostatic chuck according to an embodiment. FIGS. 5A through 5E illustrate operations of a method of manufacturing an electrostatic chuck shown in FIG. 3 according to a second embodiment.

In an embodiment and referring to FIGS. 5A through 5E, the second surface treatment device 92 may be operated by irradiating the laser L only to a pre-determined region (for example, the first zone (Z1 of FIG. 3)). In an embodiment, the second surface treatment device 92 may be configured to irradiate the laser L only to a certain area of a corresponding location by receiving coordinates of a location where the laser L is to be irradiated, and the irradiation area of the laser L. In an embodiment, the second surface treatment device 92 may be disposed under the electrostatic chuck 20, i.e., in the −z direction and may irradiate the laser L in the +z direction.

In an embodiment, the second surface treatment device 92 may inject a laser L having a certain energy density. For example, the second surface treatment device 92 may inject the laser L having an energy density of about 80 mJ/cm² to about 90 mJ/cm².

In an embodiment, the laser L irradiated to the first insulating layer 21 may not be continuously irradiated but may be irradiated with a certain frequency. For example, the second surface treatment device 92 may repeat a procedure of irradiating the laser L to the first insulating layer 21 for a certain amount of time, not irradiating the laser L for a certain amount of time and then irradiating the laser L for a certain amount of time again. In an embodiment, the above-described procedure may be repeatedly performed about 800 times.

Of course, the invention is not limited to the energy density of the laser and the number of laser irradiations, and the energy density and the number of irradiations may be changed in various ways depending on the purpose of surface treatment.

In an embodiment, the second surface treatment device 92 may irradiate the laser L to the first insulating layer 21 and then may move in one direction (for example, along an x-axis). A portion of the first insulating layer 21 to which the laser L is irradiated by the second surface treatment device 92, may be understood as the first portion 21a.

The above-described procedures may be repeatedly performed until the planar configuration and the cross-sectional configuration of the electrostatic chuck 20 shown in FIGS. 2 and 3 are achieved.

In an embodiment, a portion of the first insulating layer 21 in which surface treatment is performed by the laser L of the second surface treatment device 92, may be defined as the first portion 21a. The other portion of the first insulating layer 21, i.e., a portion that is not surface-treated, may be defined as the second portion 21b. The surface treatment may include sintering. In other words, the first portion 21a of the first insulating layer 21 may be sintered by the laser L. Thus, an ablation threshold value of the first portion 21a of the first insulating layer 21 may be increased and the first ablation threshold value of the first portion 21a may be different from the second ablation threshold value of the second portion 21b, but these features are the same as the description with reference to FIGS. 2 and 3.

Referring to the first embodiment of FIGS. 4A through 4C and the second embodiment shown in FIGS. 5A through 5E together, it may be understood that the first embodiment and the second embodiment use different methods to manufacture the same electrostatic chuck 20. For example, in the first embodiment, a region to be surface-treated using the treatment mask MS may be defined and then the laser L may be irradiated, whereas, in the second embodiment, the laser L may be precisely operated to be irradiated only to a pre-determined region. In addition, the first surface treatment device 91 of the first embodiment does not move, whereas the second surface treatment device 92 of the second embodiment may move. Meanwhile, other conditions than the irradiation region of the laser L, for example, an energy density and/or the number of irradiations may be the same both in the first embodiment and the second embodiment.

FIGS. 6A, 6B, 6C, 6D, 6E, 6F, 6G, 6H, 6I, 6J, 6K, and 6L are cross-sectional views illustrating operations of a method of manufacturing a display apparatus, according to an embodiment. The cross-sectional views shown in FIGS. 6A through 6I may represent operations of an etching process of the method of manufacturing a display apparatus.

In an embodiment and referring to FIG. 6A, the display substrate DS that is an object to be processed may be loaded into the chamber 10 using any suitable means. For example, the display substrate DS may be loaded into the chamber 10 using a robot arm.

In an embodiment, the display substrate DS in an upside down state may be loaded into the chamber 10. For example, as shown in FIG. 6A, the display substrate DS in an upside down state, i.e., in the state where the deposition layer DL is located under the substrate SUB, may be located into the chamber 10. In another embodiment, the display substrate DS in an up-straight state, for example, in the state where the deposition layer DL is located on the substrate SUB, may be loaded into the chamber 10. In this case, the display substrate DS may be reversed before the display substrate DS is combined with the electrostatic chuck 20. For example, a robot arm with the display substrate DS loaded into the chamber 10 may overturn the display substrate DS through rotation movement.

In an embodiment and referring to FIGS. 6B and 6C together, the apparatus 1 for manufacturing a display apparatus may further include a mounting unit 60, where the mounting unit 60 may include a main body 61 and a mounting pin 62 connected to the main body 61. The mounting pin 62 may extend or may be shortened in one direction (for example, along the z-axis). To this end, the main body 61 may include an arbitrary means (e.g., a linear operator) that may extend or shorten the mounting pin 62.

After the display substrate DS is loaded into the chamber 10, the display substrate DS may be aligned with the electrostatic chuck 20. In this case, the apparatus 1 for manufacturing a display apparatus may include a photographing unit (not shown) that captures an image of the location of the electrostatic chuck 20 and/or the display substrate DS.

After the locations of the electrostatic chuck 20 and the display substrate DS are moved and aligned while capturing an image of the electrostatic chuck 20 and an image of the display substrate DS, the display substrate DS may be mounted on the electrostatic chuck 20. For example, the mounting pin 62 of the mounting unit 60 may be extended to move the display substrate DS toward the electrostatic chuck 20, i.e., in the +z direction. When the display substrate DS is sufficiently moved in the +z direction, the display substrate DS may be in direct contact with the electrostatic chuck 20. For example, the substrate SUB of the display substrate DS and the first insulating layer 21 of the electrostatic chuck 20 may be in direct contact with each other.

Subsequently, an electrostatic force may be generated between the electrode layer 23 and the substrate SUB by applying a voltage to the electrode layer 23 of the electrostatic layer 20. Thus, the substrate SUB may be attached to the electrostatic chuck 20, and the display substrate DS may be mounted on the electrostatic chuck 20.

Subsequently, the display substrate DS, the electrostatic chuck 20, and the first moving unit 30 may move as a single body within the chamber 10. The display substrate DS, the electrostatic chuck 20, and the first moving unit 30 may move toward the etching unit 40, e.g., in an +x direction.

In an embodiment and referring to FIG. 6D, the electrostatic chuck 20 and the display substrate DS may be aligned with the etching unit 40.

The first zone Z1 (or the first portion 21a) of the first insulating layer 21 of the electrostatic chuck 20 may be aligned with a path of a laser of the etching unit 40. The path of the laser of the etching unit 40 is shown in a dotted line. Although not shown in FIG. 6D, the region of the display substrate DS to be etched may also be aligned with the path of the laser of the etching unit 40. In other words, the region of the display substrate DS to be etched and the first zone Z1 of the first insulating layer 21 of the electrostatic chuck 20 may be located in a straight line, for example, on a path (a dashed line) of the laser of the etching unit 40. In this case, the center of the first zone Z1 and the path (dashed line) of the laser may be aligned with each other. In an embodiment, a region of the display substrate DS to be etched, and the first zone Z1 of the first insulating layer 21 of the electrostatic chuck 20 may be aligned with each other before the display substrate DS is mounted on the electrostatic chuck 20.

In an embodiment and referring to FIG. 6E, the etching unit 40 may irradiate the laser L to the display substrate DS.

In an embodiment, the energy density of the laser L injected from the etching unit 40 may be the same as the energy density of the laser (L of FIG. 4B) injected from the first surface treatment device (91 of FIG. 4B) and the energy density of the laser (L of FIG. 5A) injected from the second surface treatment device (92 of FIG. 5A). For example, the energy density of the laser L injected from the etching unit 40 may be in a range of about 80 mJ/cm² to about 90 mJ/cm².

In an embodiment, the laser L may pass through the window 11 of the chamber 10, the second moving unit 50, and an inner space of the chamber 10 and may proceed toward the display substrate DS.

The laser L may remove (etch) a part of the deposition layer DL of the display substrate DS. In an embodiment, the laser L may be irradiated to a pre-determined area, and the deposition layer DL may be removed (etched) from the pre-determined area. Particles PT generated when a part of the deposition layer DL is etched may fall in the −z direction by gravity, for example, and may sit in the second moving unit 50.

The laser L that removes a part of the deposition layer DL of the display substrate DS may reach the substrate SUB of the display substrate DS. In this case, the substrate SUB may transmit the laser L, and the laser L may pass through the substrate SUB without etching the substrate SUB. Thus, the laser L may pass through the substrate SUB and may reach the electrostatic chuck 20. For example, the laser L may reach the first insulating layer 21 of the electrostatic chuck 20.

In an embodiment, since the first zone Z1 of the first insulating layer 21 is aligned with the path of the laser L, the laser L may be irradiated to the first portion 21a of the first insulating layer 21. If the ablation threshold value of the first insulating layer 21 is not high enough, a part of the first insulating layer 21 may be ablated by the laser L. In this case, similarly to the case of the deposition layer L, particles of the ablated first insulating layer 21 may be generated, and the particles may be adsorbed onto one surface of the substrate SUB, for example, a surface that is in contact with the first insulating layer 21. The particles adsorbed onto the surface of the substrate SUB may deteriorate the transmittance of the substrate SUB, and furthermore, may deteriorate the quality of the display substrate DS.

An ablation threshold value of the first portion 21a of the first insulating layer 21 of the electrostatic chuck 20, according to an embodiment, may be higher than the energy density of the laser L irradiated by the etching unit 40. Thus, the first portion 21a of the first insulating layer 21 may not be ablated even when the laser L is irradiated to the first portion 21a of the first insulating layer 21. Thus, the above-described particles may be prevented from being adsorbed onto the surface of the substrate SUB. In addition, since the particles may be prevented from being adsorbed onto the surface of the substrate SUB, an additional process of cleaning the surface of the substrate SUB, for example, the surface that has contacted the first insulating layer 21 may not need to be performed.

It should be appreciated that the ablation threshold value of the first portion 21a of the first insulating layer 21 of the electrostatic chuck 20 used in the above-described process may be selectively adjusted according to process conditions such as the energy density of the laser L of the etching unit 40.

In an embodiment and referring to FIG. 6F, it may be ascertained that the first opening OP1 has been formed in a portion of the deposition layer DL formed by etching the deposition layer DL using the laser L.

In an embodiment, the first opening OP1 may pass through the deposition layer DL and may overlap the first portion 21a (or the first zone Z1) of the first insulating layer 21 of the electrostatic chuck 20. A process of forming the first opening OP1 may be understood as the above-described etching process.

In an embodiment, the above-described particles PT generated while the first opening OP1 is formed, may sit in the second moving unit 50. The second moving unit 50 may move in one direction and may be discharged to the outside of the chamber 10. In one embodiment, a second moving unit 50 may be provided to discharge the particles PT to the outside of the chamber 10 and then return to the original position, and in another embodiment, a plurality of second moving units 50 may be provided to sequentially move in parallel to receive particles PT generated when forming each opening (e.g., first to fourth openings OP1, OP2, OP3 and OP4).

In an embodiment and referring to FIGS. 6G through 6I together, a similar process to the process performed in FIGS. 6D through 6F may be performed.

In an embodiment and as shown in FIG. 6G, the first moving unit 30, the electrostatic chuck 20, and the display substrate DS may move in one direction and may be newly aligned with the etching unit 40. At this time, a portion of the first portion 21a of the first insulating layer 21 other than a portion overlapping the first opening OP1 may be aligned with a laser path (indicated by a dashed line) of the etching portion 40. In this case, the deposition layer DL may not have an opening in a corresponding region.

Subsequently, as shown in FIG. 6H, a part of the deposition layer DL may be removed (etched) by irradiating the laser L to the first portion 21a of the first insulating layer 21. In this case, similarly to FIG. 6E, removed particles of the first insulating layer 21 may sit in the second moving unit 50.

Subsequently, as shown in FIG. 6I, a second opening OP2 may be formed in the deposition layer DL, and the particles PT may be discharged to the outside of the chamber 10 using the second moving unit 50. The second opening OP2 may pass through the deposition layer DL, similarly to the first opening OP1, and may overlap the first portion 21a (or the first zone Z1) of the first insulating layer 21 of the electrostatic chuck 20.

In an embodiment and referring to FIGS. 6J to 6L, the third opening OP3 and the fourth opening OP4 may be formed by repeating similar processes to the above-described process. The third opening OP3 and the fourth opening OP4 may pass through the deposition layer DL, similarly to the first opening OP1, and may overlap the first portion 21a (or the first zone Z1) of the first insulating layer 21 of the electrostatic chuck 20. After openings required for the deposition layer DL are formed, the display substrate DS may be discharged to the outside of the chamber 10 using any suitable means (for example, a robot arm).

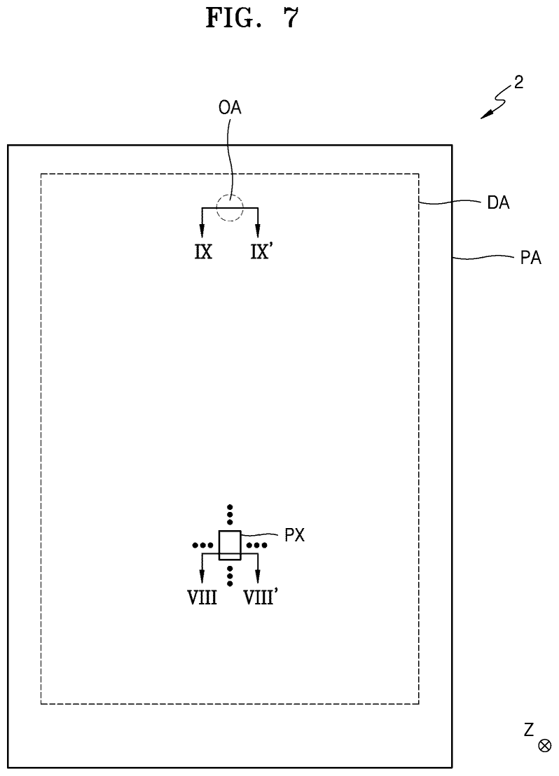

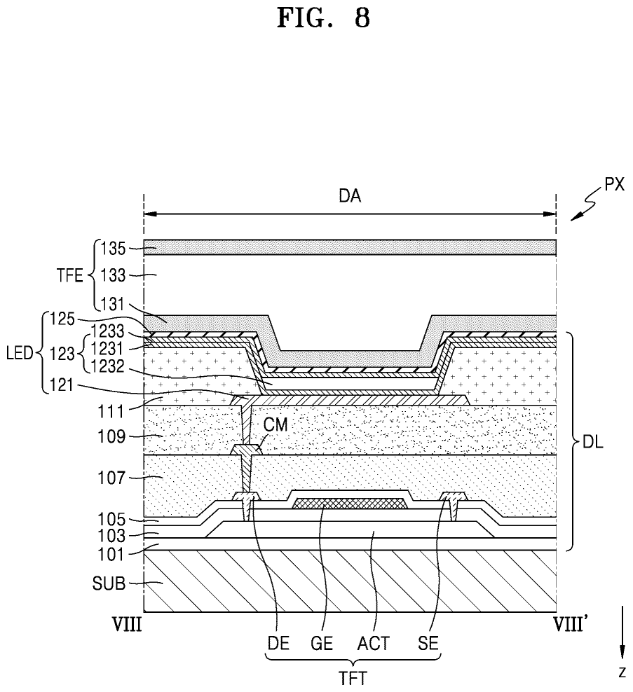

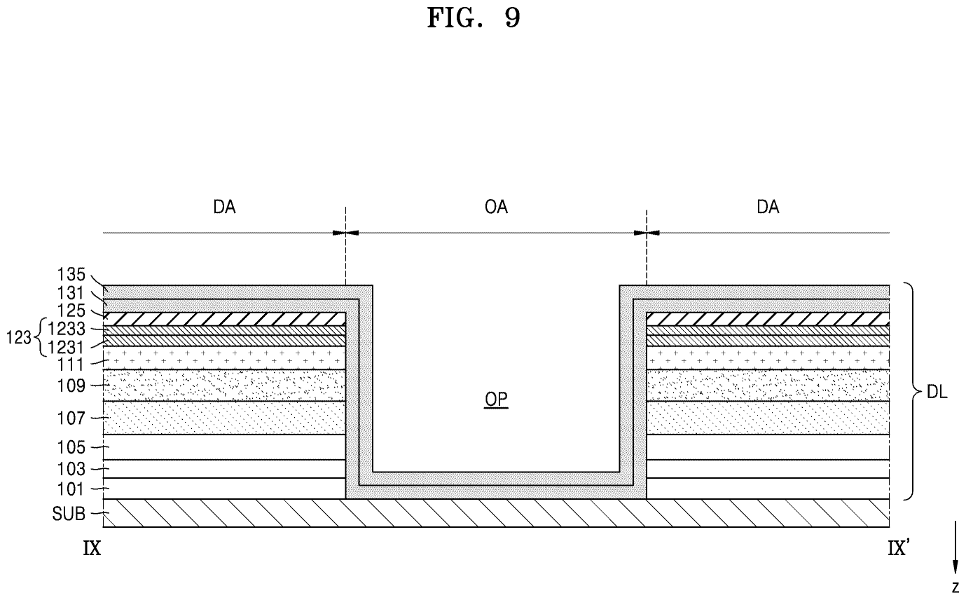

FIG. 7 is a plan view of a display apparatus manufactured by using the device for manufacturing a display apparatus, according to an embodiment. FIG. 8 is a cross-sectional view of the display apparatus of FIG. 7 taken along a line VIII-VIII′ of FIG. 7, according to an embodiment. FIG. 9 is a cross-sectional view of the display apparatus of FIG. 7 taken along a line IX-IX′ of FIG. 7, according to an embodiment.

In an embodiment and referring to FIG. 7, a display apparatus 2 may be a device for displaying a moving image or a still image and may be used for a display screen of various products such as portable electronic devices, for example, a mobile phone, a smartphone, a tablet personal computer (PC), a mobile communication terminal, an electronic notebook, an electronic book, a portable multimedia player (PMP), a navigation system, and an ultra mobile PC (PC), televisions, laptop computers, monitors, billboards, Internet of Things (IOT) devices, and the like. In addition, the display apparatus 2, according to an embodiment, may be used for a wearable device such as a smart watch, a watch phone, a glasses-type display, or an HMD. In addition, the display apparatus 2, according to an embodiment, may be used as an instrument panel of a vehicle, a center information display (CID) display disposed on a center fascia or a dashboard of a vehicle, a room mirror display for replacing a side mirror of a vehicle, and a display disposed on the rear surface of the front seat. FIG. 7 shows that the display apparatus 2, according to an embodiment, is used as a smartphone for convenience of explanation.

In an embodiment, the display apparatus 2 may have a rectangular shape in a plan view. For example, the display apparatus 2 may have a planar form of a rectangle having short sides and long sides, as shown in FIG. 7. The edges of the short sides and the long sides may be formed round or may be a right angle to have a certain curvature. The planar form of the display apparatus 2 is not limited to a rectangular shape, but can be formed in other polygonal, oval, or unstructured shapes.

In an embodiment, the display apparatus 2 may include an opening area OA and a display area DA surrounding at least the opening area OA. The display apparatus 2 may include the outside of the display area DA, for example, a peripheral area PA surrounding the display area DA.

In an embodiment, the opening area OA may be disposed outside of the display area DA. In an embodiment, the opening area OA may be disposed in the middle of the upper side of the display area DA, as shown in FIG. 7. In another embodiment, the opening area OA may be variously disposed, such as disposed on the upper left side of the display area DA or disposed on the upper right side of the display area DA. FIG. 7 illustrates that one opening area OA is disposed, but in another embodiment, a plurality of opening areas OA may be provided.

In an embodiment and referring to FIG. 8, sub-pixels PX in the display area DA are illustrated. The sub-pixels PX may include a light-emitting diode LED as a display element and a thin-film transistor TFT for driving the light-emitting diode LED.

The substrate SUB may include glass or polymer resin. In an embodiment, the substrate SUB may have an alternately-stacked structure of a base layer including polymer resin and a barrier layer including an inorganic insulating material such as silicon oxide or silicon nitride. The polymer resin may include polymer resin such as polyethersulfone, polyarylate, polyether imide, polyethylene naphthalate, polyethylene teraphthalate, polyphenylene sulfide, polyimide, polycarbonate, cellulose triacetate, or celluose acetate propionate.

In an embodiment, a deposition layer DL may be arranged on the substrate SUB. The deposition layer DL may be formed on the substrate SUB using a deposition process, where the deposition layer DL may include a buffer layer 101, an active layer ACT, a gate insulating layer 103, a gate electrode GE, an interlayer insulating layer 105, a source electrode SE, a drain electrode DE, a first organic insulating layer 107, a second organic insulating layer 109, a pixel defining layer 111, a sub-pixel electrode 121, an intermediate layer 123, and an opposite electrode 125.

The buffer layer 101 may be arranged on the substrate SUB and may be configured to planarize the upper surface of the substrate SUB and to protect the substrate SUB. The buffer layer 101 may include an inorganic insulating material such as silicon oxide (SiOₓ), silicon nitride (SiNₓ) and/or silicon oxynitride (SiOₓN_{y}), and may have a single layer or multi-layered structure of the above-described materials. Although not shown in FIG. 8, in another embodiment, a barrier layer may be additionally disposed between the substrate SUB and the buffer layer 101, where the barrier layer may include a similar material to the buffer layer 101.

In an embodiment, the thin-film transistor TFT may be arranged on the buffer layer 101 and may include an active layer ACT, a gate electrode GE, a source SE, and a drain electrode DE.

The active layer ACT may be disposed on the buffer layer 101 and may include a drain region that overlaps the drain electrode DE, a source region that overlaps the source electrode SE, and a channel region between the drain region and the source region. The source region and the drain region of the active layer ACT may be regions doped with impurities.

In an embodiment, the gate insulating layer 103 may be arranged on the active layer ACT and may include an inorganic material including oxide or nitride. For example, the gate insulating layer 103 may include at least one of silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and zinc oxide (ZnO₂), and may have a single layer or multi-layered structure of the above-described materials.

The gate electrode GE may be disposed on the gate insulating layer 103, where at least a part of the gate electrode GE may overlap the active layer ACT. For example, the gate electrode GE may be disposed to overlap a channel region of the active layer ACT. The gate electrode GE may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single layer or multi-layered structure including the materials described above.

In an embodiment, the interlayer insulating layer 105 may be provided to cover the gate electrode GE, where the interlayer insulating layer 105 may include an inorganic material including oxide or nitride. For example, the interlayer insulating layer 105 may include at least one of silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and zinc oxide (ZnO₂), and may have a single layer or multi-layered structure of the above-described materials.

In an embodiment, the gate insulating layer 103 and the interlayer insulating layer 105 may include contact holes that overlap the source region and the drain region of the active layer ACT. The source electrode SE and the drain electrode DE may be disposed above the interlayer insulating layer 105. The source electrode SE may be disposed to overlap the source region of the active layer ACT, and the drain electrode DE may be disposed to overlap the drain region of the active layer ACT. Each of the source electrode SE and the drain electrode DE may be connected to the active layer ACT through the contact holes formed in the gate insulating layer 103 and the interlayer insulating layer 105.

In an embodiment, the first organic insulating layer 107 may be disposed to cover the buffer layer 101, the gate insulating layer 103, the interlayer insulating layer 105, and the thin-film transistor TFT. The second organic insulating layer 109 may be located on the first organic insulating layer 107.

The first organic insulating layer 107 may include contact holes that overlap the drain electrode DE. A contact metal CM may be disposed on the upper surface of the first organic insulating layer 107 and may be electrically connected to the drain electrode DE via the contact holes of the first organic insulating layer 107. The second organic insulating layer 109 may include contact holes overlapping the contact metal CM. The sub-pixel electrode 121 may be disposed on the upper surface of the second organic insulating layer 109 and may be electrically connected to the contact metal CM via the contact holes of the second organic insulating layer 109. Thus, the sub-pixel electrode 121 may be electrically connected to the drain electrode DE of the thin-film transistor TFT via the contact metal CM.

FIG. 8 illustrates an embodiment having two organic insulating layers (e.g., the first organic insulating layer 107 and the second organic insulating layer 109) and one contact metal CM, but the invention is not limited thereto. In another embodiment, N (where N is a natural number that is greater than or equal to 3) organic insulating layers and (N−1) contact metals may be provided. In still another embodiment, one organic insulating layer may be provided, and the contact metal may be omitted.

The first organic insulating layer 107 and the second organic insulating layer 109 may include general-purpose polymer such as benzocyclobutene, polyimide, hexamethyldisiloxane, polymethylmethacrylate or polystyrene. a polymer derivative having a phenol-based group, acryl-based polymer, imide-based polymer, aryl ether-based polymer, amide-based polymer, fluorine-based polymer, p-xylene-based polymer, or vinyl alcohol-based polymer, and may have a single layer or multi-layered structure of the above-described materials. In an embodiment, the first organic insulating layer 107 and the second organic insulating layer 109 may include the same material. In an embodiment, the first organic insulating layer 107 and the second organic insulating layer 109 may include different materials. In an embodiment, the first organic insulating layer 107 and/or the second organic insulating layer 109 may include a plurality of layers including different materials.

In an embodiment, the sub-pixel electrode 121 may be located on the upper surface of the second organic insulating layer 109. As described above, the second sub-pixel electrode 121 may be electrically connected to the contact metal CM via the contact holes formed in the second organic insulating layer 109.

The sub-pixel electrode 121 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The sub-pixel electrode 121 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. Of course, a configuration and a material of the sub-pixel electrode 121 are not limited thereto, and various modifications are possible.

In an embodiment, the pixel defining layer 111 may be located on the upper surface of the second organic insulating layer 109 and may cover the edge (or an edge area) of the sub-pixel electrode 121. In other words, the pixel defining layer 111 may be open to expose a part of the center of the sub-pixel electrode 121. The size and shape of an emission region of the light-emitting diode LED may be determined by the opening of the pixel defining layer 111.

In an embodiment, an intermediate layer 123 may be disposed on the sub-pixel electrode 121, where the intermediate layer 123 may include a first functional layer 1231 and a second functional layer 1233 disposed on the pixel defining layer 111, and a light-emitting layer 1232 disposed in the opening of the pixel defining layer 111. The first functional layer 1231 may be disposed on the pixel defining layer 111, and the second functional layer 1233 may be disposed on the first functional layer 1231. The light-emitting layer 1232 may be disposed in the opening of the pixel defining layer 111 and may be disposed between the first functional layer 1231 and the second functional layer 1233. That is, the first functional layer 1231 may be disposed on the pixel defining layer 111, the light-emitting layer 1232 may be disposed on the first functional layer, and the second functional layer 1233 may be disposed on the first functional layer 1231 to cover the light-emitting layer 1232.

In an embodiment, the light-emitting layer 1232 may include an organic emission layer including a low molecular weight material or polymer material. The first functional layer 1231 may include an electron transport layer (ETL) and/or an electron injection layer (EIL). The second functional layer 1233 may include, for example, a hole transport layer (HTL) or an HTL and a hole injection layer (HIL). In another embodiment, the first functional layer 1231 or the second functional layer 1233 may be omitted. In still another embodiment, the positions of the first functional layer 1231 and the second functional layer 1233 may be changed with each other.

In an embodiment, an opposite electrode 125 may be arranged on the intermediate layer 123. For example, the opposite electrode 125 may be disposed on the second functional layer 1233, where the opposite electrode 125 may be disposed to entirely cover the intermediate layer 123. The opposite electrode 125 may include a conductive material having a low work function. For example, the opposite electrode 125 may include a (semi-)transparent layer including Ag, Mg, Al, Pt, Pd, Au, Ni, Nd, Ir, Cr, Li, Ca or an alloy thereof. In another embodiment, the opposite electrode 125 may further include a layer such as ITO, IZO, ZnO or In₂O₃ on the (semi-)transparent layer including the above-described materials.

In an embodiment, the thin-film encapsulation layer TFE may be disposed on the opposite electrode 125 and may entirely cover the light-emitting diode LED. The thin-film encapsulation layer TFE may include at least one inorganic encapsulation layer and at least one organic encapsulation layer. In an embodiment, the thin-film encapsulation layer TFE may include a first inorganic encapsulation layer 131 and a second inorganic encapsulation layer 135, and may include an organic encapsulation layer 133 disposed between the first inorganic encapsulation layer 131 and the second inorganic encapsulation layer 135.

The first inorganic encapsulation layer 131 and the second inorganic encapsulation layer 135 may include an inorganic insulating material such as silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The organic encapsulation layer 133 may include a polymer-based material. The polymer-based material may include a silicon-based resin, an acryl-based resin, an epoxy-based resin, polyimide, polyethylene, or the like.

In an embodiment and referring to FIG. 9, the substrate SUB and the deposition layer DL may be disposed near the opening area OA.

In an embodiment, the deposition layer DL may define an opening OP that overlaps the opening area OA. For example, each of the buffer layer 101, the gate insulating layer 103, the interlayer insulating layer 105, the first organic insulating layer 107, the second organic insulating layer 109, the pixel defining layer 111, the first functional layer 1231, the second functional layer 1233, and the opposite electrode 125 may include a corresponding opening, and openings of each layer may form the opening OP of the deposition layer DL collectively. FIG. 9 illustrates that edges of openings of each layer coincide with each other, but the invention is not limited thereto. FIG. 9 illustrates that the side surface of the opening OP of the deposition layer DL is directed parallel to a z-axis, but the invention not limited thereto.

In an embodiment, a part of the first inorganic encapsulation layer 131 and the second inorganic encapsulation layer 135 may be disposed in the opening OP and may cover the deposition layer DL and the substrate SUB.

The opening OP of the deposition layer DL described above may be formed using a device for manufacturing a display apparatus, according to an embodiment. For example, in a state in which the opening OP is not present in the deposition layer DL (see FIG. 6D), a part of the deposition layer DL may be etched using the device for manufacturing a display apparatus to form the opening OP. Referring to FIG. 6L together, the opening OP of the deposition layer DL of FIG. 9 may be understood to correspond to one of the openings OP1 through OP4 of FIG. 6L. Thus, the first opening OP1 through the fourth opening OP4 may be understood to correspond to the opening OP of the deposition layer DL of each of a plurality of different display apparatuses. In this case, it may be understood that a plurality of display apparatuses are manufactured within the device for manufacturing a display apparatus at one time.

According to one or more embodiments, an electrostatic chuck in which the surface of a display apparatus is not ablated by a laser during laser etching, can be implemented. Thus, a part of the electrostatic chuck can be prevented from being ablated during laser etching of the display apparatus, and particles of the electrostatic chuck can be prevented from being adsorbed onto a rear surface of a substrate. Thus, a display apparatus in which the transmittance of the substrate may be enhanced and quality may be enhanced, can be implemented. In addition, since the particles are not adsorbed onto the rear surface of the substrate, a substrate rear surface cleaning process of removing the particles may be omitted.

The effects of the invention are not limited to the aforementioned objectives, and other effects not mentioned can be clearly understood by a person skilled in the art from the above description.

It should be understood that embodiments described herein should be considered in a descriptive sense only and not for purposes of limitation. Descriptions of features or aspects of each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the invention. Moreover, the embodiments or parts of the embodiments may be combined in whole or in part without departing from the scope of the invention.

What is claimed is:

1. An electrostatic chuck comprising:
a first insulating layer;
a second insulating layer; and
an electrode layer disposed between the first insulating layer and the second insulating layer,
wherein the first insulating layer comprises a first zone and a second zone disposed on a surface facing a first direction and disposed away from the second insulating layer, wherein the second zone at least partially surrounds the first zone, and
wherein a first ablation threshold value of the first insulating layer in the first zone is different from a second ablation threshold value of the first insulating layer in the second zone.

2. The electrostatic chuck of claim 1, wherein the first ablation threshold value of the first insulating layer in the first zone is greater than the second ablation threshold value of the first insulating layer in the second zone.

3. The electrostatic chuck of claim 1, wherein, when viewed from the first direction, the first zone comprises a plurality of opening shapes that are spaced apart from each other.

4. The electrostatic chuck of claim 1, wherein the first ablation threshold value is about 1000 mJ/cm² or greater.

5. A method of manufacturing an electrostatic chuck, the method comprising:
preparing a first insulating layer, a second insulating layer, and an electrode layer disposed between the first insulating layer and the second insulating layer; and
irradiating a laser to a first zone on a first surface of the first insulating layer, wherein the first zone is facing in a first direction and is disposed away from the second insulating layer.

6. The method of claim 5, wherein the irradiating of the laser comprises sintering the first insulating layer in the first zone.

7. The method of claim 5, wherein the irradiating of the laser comprises increasing an ablation threshold value of the first insulating layer in the first zone.

8. The method of claim 5, wherein, when viewed from the first direction, the first zone comprises a plurality of opening shapes that are spaced apart from each other.

9. The method of claim 5, further comprising arranging a mask including an opening overlapping the first zone on the first surface of the first insulating layer and the laser is irradiated to the mask.

10. The method of claim 5, wherein, in the irradiating of the laser, the laser is selectively irradiated to the first zone.

11. The method of claim 5, wherein an energy density of the laser is in a range of about 80 mJ/cm² to about 90 mJ/cm².

12. The method of claim 5, wherein the electrode layer is disposed on the first insulating layer, the second insulating layer is disposed on the first insulating layer, and the laser is irradiated to the first surface of the first insulating layer which is disposed under the first insulating layer.

13. A device for manufacturing a display apparatus, the device comprising:
a chamber;
an electrostatic chuck disposed in the chamber and being in close contact with a display substrate; and
an etching unit configured to irradiate a laser to the display substrate,
wherein the electrostatic chuck comprises:
a first insulating layer and a second insulating layer that are in contact with the display substrate, and an electrode layer disposed between the first insulating layer and the second insulating layer,
wherein the first insulating layer comprises a first zone and a second zone disposed on a first surface and being in contact with the display substrate, the second zone at least partially surrounding the first zone, and
wherein a first ablation threshold value of the first insulating layer in the first zone is different from a second ablation threshold value of the first insulating layer.

14. The device of claim 13, wherein the first ablation threshold value is greater than the second ablation threshold value.

15. The device of claim 13, wherein the first zone comprises a plurality of opening shapes that are spaced apart from each other.

16. The device of claim 13, wherein the first ablation threshold value is about 1000 mJ/cm² or greater.

17. The device of claim 13, wherein the etching unit is disposed outside the chamber.

18. The device of claim 13, wherein the display substrate is disposed under the electrostatic chuck, the etching unit is disposed under the display substrate, and a direction of the laser is directed entirely upward.

19. The device of claim 13, wherein the etching unit is configured to irradiate a laser to the display substrate in a region overlapping the first zone of the first insulating layer.

20. The device of claim 13, wherein the laser is configured to etch a partial layer of the display substrate, pass through an other layer of the display substrate and reach the electrostatic chuck.
